(19) United States
(12) Patent Application Publication
(10) Pub. No.: US 2026/0170980 A1
(43) Pub. Date: Jun. 18, 2026

(54) DISPLAY PANEL FOR STRETCHABLE DISPLAY DEVICE

(71) Applicant: LG Display Co., Ltd., Seoul (KR)

(72) Inventors: Hae-Yoon JUNG, Paju-si (KR); Ae-Sun KIM, Paju-si (KR); Su-Jin HAM, Paju-si (KR); Myung-Sub LIM, Paju-si (KR); Yu-Ra JEONG, Paju-si (KR); In-Jun LEE, Paju-si (KR)

(73) Assignee: LG Display Co., Ltd., Seoul (KR)

(21) Appl. No.: 19/376,823

(22) Filed: Oct. 31, 2025

(30) Foreign Application Priority Data
Dec. 12, 2024 (KR) 10-2024-0185139

(51) Int. Cl. G09G 3/00; H10H 29/01; H10H 29/49

(52) U.S. Cl. CPC G09G 3/006; H10H 29/012; H10H 29/49; G09G 2330/08; G09G 2330/12; G09G 2380/02

(57) ABSTRACT

A display panel for a stretchable display device has a rigid part and a soft part and includes a base substrate in the rigid part and the soft part; a planarization layer over the base substrate and in the rigid part; a pixel on the base substrate in the rigid part and including a first electrode over the planarization layer, a second electrode over the planarization layer and spaced apart from the first electrode, and a light emitting element electrically connected to the first and second electrodes; a first stretchable line disposed along a first direction and having an end on the planarization layer and a center portion on the base substrate in the soft part; and a repair line between the base substrate and the planarization layer. The repair line may be disposed along at least three sides of the pixel and overlap the first stretchable line.

### CROSS-REFERENCE TO RELATED APPLICATION

The present application claims the benefit of Korean Patent Application No. 10-2024-0185139, filed in the Republic of Korea on Dec. 12, 2024, which is hereby incorporated by reference in its entirety.

### FIELD OF TECHNOLOGY

The present disclosure relates to a display device and, more specifically, to a display panel for a stretchable display device configured for a repair of a line defect.

### BACKGROUND

As the information society progresses, interest in displays that process and display a large amount of information has been increasing, and various types of displays have been developed.

Accordingly, in addition to a commonly known rectangular display, flexible display devices, such as a bendable display device for gaming, a foldable display device capable of being folded and unfolded, and a rollable display device having optimal space utilization, have been widely developed.

Recently, a stretchable display device, which is much more flexible than these flexible display devices, has been in the spotlight as a next-generation display.

The stretchable display device is a display that can freely transform the shape of a screen without distortion even when the screen is increased in size, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device may include a rigid part in which a pixel is disposed and a soft part in which a connection line connecting the pixels is disposed. The rigid part may not be stretched, and the soft part may be stretched.

### SUMMARY

The present disclosure is directed to a display panel for a stretchable display device that substantially obviates one or more of the problems associated with the limitations and disadvantages of the related art.

An object of the present disclosure is to provide a display panel for a stretchable display device configured for a repair of a line defect.

Additional features and advantages of the present disclosure are set forth in the description which follows, and will be apparent from the description, or evident by practice of the present disclosure. The objectives and other advantages of the present disclosure can be realized and attained by the features described herein as well as in the appended drawings.

To achieve these and other advantages in accordance with the purpose of the embodiments of the present disclosure, as described herein, an aspect of the present disclosure is a display panel for a stretchable display device having a rigid part and a soft part and including a base substrate in the rigid part and the soft part; a planarization layer over the base substrate and in the rigid part; a pixel on the base substrate in the rigid part and including a first electrode over the planarization layer, a second electrode over the planarization layer and spaced apart from the first electrode, and a light emitting element electrically connected to the first and second electrodes; a first stretchable line disposed along a first direction in a plan view and having an end on the planarization layer and a center portion on the base substrate in the soft part; and a repair line between the base substrate and the planarization layer. The repair line may be disposed along at least three sides of the pixel in the plan view and overlap the first stretchable line.

It is to be understood that both the foregoing general description and the following detailed description are by way of example and explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this specification, illustrate example embodiments of the present disclosure and together with the description serve to explain various principles of the present disclosure.

FIG. 1 is a schematic plan view of a display panel for a stretchable display device according to example embodiments of the present disclosure.

FIG. 2 is a schematic cross-sectional view of a display panel for a stretchable display device according to the first example embodiment of the present disclosure.

FIG. 3 is a schematic plan view for explaining a repair process in a display panel for a stretchable display device according to the first example embodiment of the present disclosure.

FIG. 4 is a schematic cross-sectional view of a display panel for a stretchable display device according to a second example embodiment of the present disclosure.

FIG. 5 is a schematic cross-sectional view of a display panel for a stretchable display device according to a third example embodiment of the present disclosure.

FIG. 6 is a schematic plan view of a display panel for a stretchable display device according to a fourth example embodiment of the present disclosure.

FIG. 7 is a schematic cross-sectional view of a display panel for a stretchable display device according to the fourth example embodiment of the present disclosure.

### DETAILED DESCRIPTION

Reference will now be made in detail to aspects of the present disclosure, examples of which may be illustrated in the accompanying drawings. In the following description, where a detailed description of well-known functions or configurations related to this disclosure may unnecessarily cloud a feature or aspect of the present disclosure, the detailed description of such well-known functions or configurations may be omitted. The progression of processing steps and/or operations described is an example, and the sequence of steps and/or operations is not limited to that set forth herein and may be changed as is known in the art, with the exception of steps and/or operations necessarily occurring in a particular order. Names of the respective elements used in the following explanations are selected only for convenience of writing the specification and may thus be different from those used in actual products.

Advantages and features of the present disclosure and methods of achieving them will be apparent with reference to the examples or aspects described below in detail with the accompanying drawings. However, the present disclosure is not limited to the examples or aspects disclosed below, but can be realized in a variety of different forms. The present disclosure is provided to fully inform the scope of the disclosure to those skilled in the art related to the present disclosure.

The shapes, sizes, proportions, angles, numbers, and the like disclosed in the drawings for explaining various aspects of the present disclosure are illustrative examples, and the present disclosure is not limited to such illustrated examples. The same reference numerals refer to the same elements throughout the specification unless otherwise specified.

Where terms like “including,” “having,” and “consisting” are used in this specification, other parts may be added unless a more specific term like “only” is used. Where a component is expressed in the singular, cases including the plural are included unless otherwise specified.

In construing an element, the element is to be construed as including an error or tolerance range even where there is no explicit description of such an error or tolerance range.

Where a positional relationship is described, for example, where a positional relationship between two parts is described as, for example, “on,” “over,” “under,” and “next,” one or more other parts may be disposed between the two parts unless a more limiting term, such as “just” or “direct(ly),” is used.

It should be understood that, although terms like “first” and “second” may be used herein to describe various elements, these elements should not be limited by these terms. These terms are only used to refer to one element separately from another. For example, a first element could be termed a second element, and, similarly, a second element could be termed a first element, without departing from the scope of the present disclosure.

Reference will now be made in detail to some example embodiments, which are illustrated in the accompanying drawings.

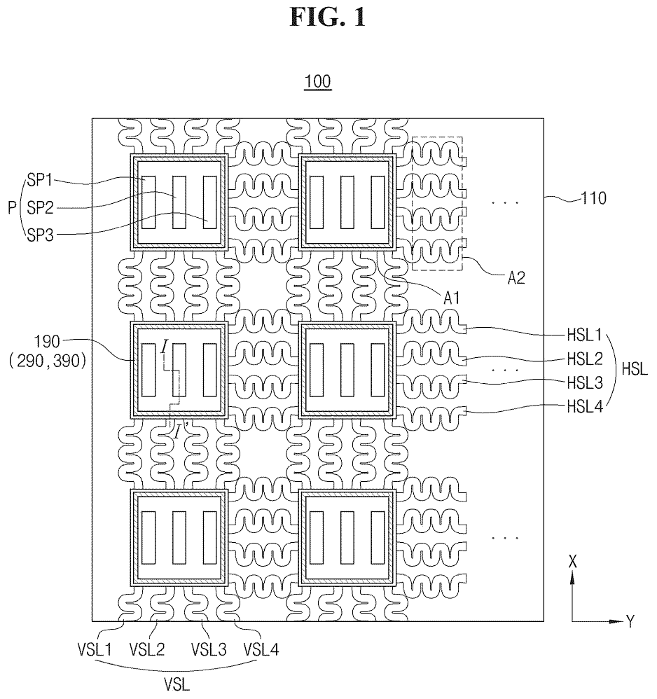

FIG. 1 is a schematic plan view of a display panel for a stretchable display device according to a first example embodiment of the present disclosure.

A display panel 100 can be stretched along a first direction X and/or a second direction Y. As shown in FIG. 1, the display panel 100 includes a base substrate 110, and a rigid part (e.g., rigid portion, a hard part, or a hard portion) A1 corresponding to a pixel region and a soft part (e.g., a soft portion) A2 corresponding to a stretchable region are provided on the base substrate 110. The rigid part A1 is not stretched, and the soft part A2 can be stretched.

A plurality of rigid parts A1 each having an island shape are provided. The rigid parts A1 are spaced apart from each other in the first and second directions X and Y. For example, the rigid part A1 may have a square or rectangular shape, but the present disclosure is not limited thereto.

A pixel P including a plurality of subpixels SP1, SP2, and SP3 are provided in the rigid part A1. For example, a first subpixel SP1, a second subpixel SP2, and a third subpixel SP3 may be provided in the rigid part A1, and the first to third subpixels SP1, SP2, and SP3 may be red, green, and blue subpixels, respectively. The first to third subpixels SP1, SP2, and SP3 may be arranged along the second direction Y.

Each of the first to third subpixels SP1, SP2, and SP3 may include a light emitting element and at least one transistor. In addition, each of the first to third subpixels SP1, SP2, and SP3 may further include at least one capacitor.

The soft part A2 is positioned between adjacent rigid parts A1 in the first and second directions X and Y. For example, the soft part A2 may surround the rigid part A1.

A stretchable lines VSL and HSL (e.g., stretchable signal lines) connecting adjacent pixels P are provided in the soft part A2. The stretchable lines VSL and HSL may include a plurality of signal lines (e.g., a plurality voltage lines), such as a gate line, a data line, a high-level line (e.g., high-level voltage line), a low-level line (e.g., a low-level voltage line), an emission signal line, or a reference voltage line.

Vertical stretchable lines VSL (e.g., first stretchable lines) may include first, second, third, and fourth vertical stretchable lines VSL1, VSL2, VSL3, and VSL4. The vertical stretchable lines VSL extend along the first direction X. For example, the first vertical stretchable line VSL1 may be the reference voltage line, and each of the second to fourth vertical stretchable lines VSL2 to VSL4 may be the first to third data lines for applying a data signal to the first to third subpixels SP1 to SP3, respectively. For example, each of the first to fourth vertical stretchable lines VSL1 to VSL4 may include a first line segment connected to one side of a pixel P and a second line segment connected to the other side of that pixel P.

Horizontal stretchable lines HSL (e.g., second stretchable lines) may include first, second, third, and fourth horizontal stretchable lines HSL1, HSL2, HSL3, and HSL4. The horizontal stretchable lines HSL extend along the second direction Y. For example, the first horizontal stretchable line HSL1 may be the high-level line, and the second horizontal stretchable line HSL2 may be the gate line. The third horizontal stretchable line HSL3 may be the emission signal line, and the fourth horizontal stretchable line HSL4 may be the low-level line. For example, each of the first to fourth horizontal stretchable lines HSL1 to HSL4 may include a first line segment connected to one side of a pixel P and a second line segment connected to the other side of that pixel P.

The stretchable lines VSL and HSL may include at least one curved portion. For example, the stretchable lines VSL and HSL may have a wave structure and include a plurality of wave shapes.

The display panel 100 includes a repair line 190 surrounding the pixel P. For example, the repair line 190 may surround each of the rigid parts A1. The repair line 190 surrounding the pixel P is spaced apart from the repair line 190 surrounding an adjacent pixel P.

For example, the repair line 190 may have a ring shape, e.g., a square or rectangular ring shape. In another example embodiment of the present disclosure, the repair line 190 may be disposed along three sides of the pixel P and may be opened at one side of the pixel P. For example, the repair line 190 may have a “C” or “U” shape.

When a line defect occurs in the display panel 100 for the stretchable display device according to the first example embodiment of the present disclosure, one of the stretchable lines VSL and HSL can be cut, and the repair line 190 can be used as a bypass. Accordingly, the line defect in the display panel 100 can be converted into a point defect.

As a result, the display panel 100 and the stretchable display device including the same can provide high quality images.

In addition, by reducing the load on the display panel 100 by converting a defective pixel into a point defect, the lifespan of the display panel 100 can be improved, and the low power consumption can be realized.

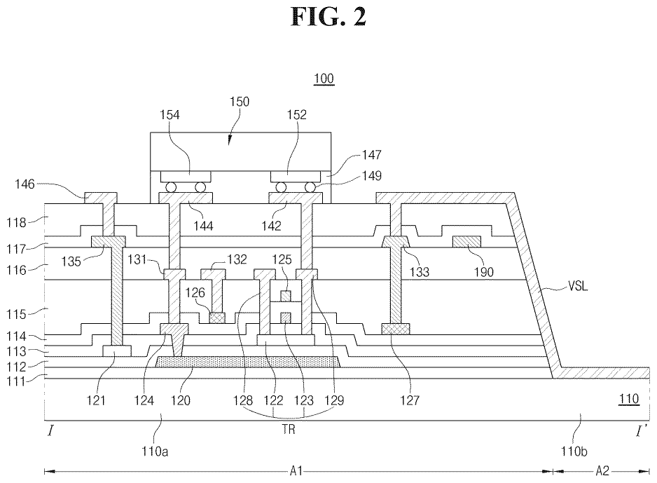

FIG. 2 is a schematic cross-section view of a display panel for a stretchable display device according to the first example embodiment of the present disclosure. FIG. 2 shows a cross-section view taken along the line I-I′ in FIG. 1.

As illustrated in FIG. 2 in combination with FIG. 1, the display panel 100 for the stretchable display device according to the first example embodiment of the present disclosure includes the base substrate 110. A rigid part A1 corresponding to a pixel region and a soft part A2 corresponding to a stretchable region are provided on the base substrate 110. An insulating layers, e.g., a first buffer layer 111, a second buffer layer 112, a gate insulating layer 113, a first interlayer insulating layer 114, a second interlayer insulating layer 115, a third interlayer insulating layer 116, a passivation layer 117 or a planarization layer 118, on the base substrate 110 in a portion of the soft part A2 are removed so that the rigidity of the base substrate 110 in the soft part A2 is weakened. As a result, the rigid part A1 and the soft part A2 are provided.

The base substrate 110 includes a first base portion 110a and a second base portion 110b. The first base portion 110a corresponds to the rigid part A1, and the second base portion 110b corresponds to the soft part A2.

The first base portion 110a is provided as a plate shape in a display region. A plurality of first base portions 110a are spaced apart from each other in the first and second directions X and Y. The first base portion 110a is configured to support and protect elements of the subpixels SP1, SP2 and SP3.

The second base portion 110b is positioned between adjacent first base portions 110a. The second base portion 110b includes at least one curved portion. The second base portion 110b is configured to support and protect the stretchable lines VSL and HSL.

The first and second base portions 110a and 110b may be connected and provided as one integrated body. For example, the second base portion 110b may be branched (or extended) along the first direction X from the first base portion 110a to correspond to the vertical stretchable lines VSL and may be branched (or extended) along the second direction Y from the first base portion 110a to correspond to the horizontal stretchable lines HSL.

For example, the second base portion 110b along the first direction X may correspond to each of the first to fourth vertical stretchable lines VSL1 to VSL4, and the second base portion 110b along the second direction Y may correspond to each of the first to fourth horizontal stretchable lines HSL1 to HSL4.

A first soft substrate (e.g., flexible substrate) (not illustrated) may be attached to a rear side of the base substrate 110 by using an adhesive layer, and a second soft substrate (not illustrated) may be attached to a front side of the base substrate 110 to be disposed over the light emitting diode as the light emitting element.

The base substrate 110 includes (or is formed of) a rigid material having a relatively low flexibility. The base substrate 110 may have a flexibility being lower than each of the first and second soft substrates. For example, the base substrate 110 may be formed of a polyimide-based resin or an epoxy-based resin.

The base substrate 110 has a relatively high elastic modulus, and the elastic modulus of the base substrate 110 may be higher than the elastic modulus of the first and second soft substrates. For example, the elastic modulus of the base substrate 110 may be at least 1000 times higher than the elastic modulus of the first and second soft substrates, but embodiments of the present disclosure are not limited thereto.

A first buffer layer 111 as a first insulating layer is disposed over the base substrate 110. For example, the first buffer layer 111 may include an inorganic insulating material, e.g., silicon nitride, silicon oxide, or silicon oxynitride.

To prevent or suppress a potential damage, e.g., cracks, in the first buffer layer 111 due to stretching, the first buffer layer 111 may be removed from the soft part A2 to substantially correspond to the rigid part A1. As a result, the first buffer layer 111 may be provided on the first base portion 110a and not provided on the second base portion 110b.

A light shielding layer 120 is disposed on the first buffer layer 111 in the rigid part A1. The light shielding layer 120 may be formed of a conductive material, such as metal. For example, the light shielding layer 120 may be formed of at least one of aluminum (Al), copper (Cu), molybdenum (Mo), titanium (Ti), chromium (Cr), nickel (Ni), tungsten (W), and their alloys.

A second buffer layer 112 as a second insulating layer is disposed on the light shielding layer 120. For example, the second buffer layer 112 may include an inorganic insulating material, e.g., silicon nitride, silicon oxide, or silicon oxynitride.

The second buffer layer 112 may be removed from the soft part A2 to substantially correspond to the rigid part A1. As a result, the second buffer layer 112 may be provided on the first base portion 110a and not provided on the second base portion 110b.

A semiconductor layer 122 is disposed on the second buffer layer 112. The semiconductor layer 122 may overlap the light shielding layer 120. The light shielding layer 120 blocks the light to the semiconductor layer 122 so that the thermal degradation of the semiconductor layer 122 can be prevented or suppressed.

The semiconductor layer 122 may include a channel region and source and drain regions at both sides of the channel region.

The semiconductor layer 122 may be formed of an oxide semiconductor material. Alternatively, in another example embodiment of the present disclosure, the semiconductor layer 122 may be formed of poly-crystalline silicon.

A semiconductor pattern 121 may be disposed on the second buffer layer 112. The semiconductor pattern 121 may be formed of the same material as the semiconductor layer 122.

A gate insulating layer 113 as a third insulating layer is disposed on the semiconductor layer 122 and the semiconductor pattern 121. For example, the gate insulating layer 113 may include an inorganic insulating material, e.g., silicon nitride, silicon oxide, or silicon oxynitride.

The gate insulating layer 113 may be removed from the soft part A2 to substantially correspond to the rigid part A1. As a result, the gate insulating layer 113 may be provided on the first base portion 110a and not provided on the second base portion 110b.

A gate electrode 123 and a first connection electrode 124 are disposed on the gate insulating layer 113.

The gate electrode 123 may overlap the semiconductor layer 122 and correspond to the channel region of the semiconductor layer 122. As a result, the gate electrode 123 may overlap the light shielding layer 120.

The first connection electrode 124 is spaced apart from the semiconductor layer 122 and overlaps the light shielding layer 120. The first connection electrode 124 may contact the light shielding layer 120 through a contact hole in the second buffer layer 112 and the gate insulating layer 113.

Each of the gate electrode 123 and the first connection electrode 124 may be formed of a conductive material, such as metal. For example, each of the gate electrode 123 and the first connection electrode 124 may be formed of at least one of Al, Cu, Mo, Ti, Cr, Ni, W, and their alloys.

A first interlayer insulating layer 114 as a fourth insulating layer is disposed on the gate electrode 123 and the first connection electrode 124. For example, the first interlayer insulating layer 114 may include an inorganic insulating material, e.g., silicon nitride, silicon oxide, or silicon oxynitride.

The first interlayer insulating layer 114 may be removed from the soft part A2 to substantially correspond to the rigid part A1. As a result, the first interlayer insulating layer 114 may be provided on the first base portion 110a and not provided on the second base portion 110b.

An auxiliary electrode 125, an auxiliary line 126, and a pad electrode 127 are disposed on the first interlayer insulating layer 114.

Each of the auxiliary electrode 125, the auxiliary line 126, and the pad electrode 127 may be formed of a conductive material such, as metal. For example, each of the auxiliary electrode 125, the auxiliary line 126 and the pad electrode 127 may be formed of at least one of Al, Cu, Mo, Ti, Cr, Ni, W, and their alloys.

A second interlayer insulating layer 115 as a fifth insulating layer is disposed on the auxiliary electrode 125, the auxiliary line 126, and the pad electrode 127. The second interlayer insulating layer 115 may be formed of an inorganic insulating material or an organic insulating material. For example, the second interlayer insulating layer 115 may include an inorganic insulating material, e.g., silicon nitride, silicon oxide, or silicon oxynitride, or an organic insulating material, e.g., photo-acryl or benzocyclobutene.

The second interlayer insulating layer 115 may be removed from the soft part A2 to substantially correspond to the rigid part A1. As a result, the second interlayer insulating layer 115 may be provided on the first base portion 110a and not provided on the second base portion 110b.

A source electrode 128, a drain electrode 129, a second connection electrode 131, and a power line 132 are disposed on the second interlayer insulating layer 115. The source electrode 128 and the drain electrode 129 contact respective sides of the semiconductor layer 122, i.e., the source region and the drain region, respectively, through contact holes in the first and second interlayer insulating layers 114 and 115 and the gate insulating layer 113.

The source electrode 128, the drain electrode 129, the gate electrode 123, and the semiconductor layer 122 constitute a thin film transistor (TFT) TR.

The second connection electrode 131 is spaced apart from the TFT TR and overlaps the first connection electrode 124. The second connection electrode 131 contacts the first connection electrode 124 through a contact hole in the first and second interlayer insulating layers 114 and 115.

The power line 132 contacts the auxiliary line 126 through a contact hole in the second interlayer insulating layer 115. For example, the power line 132 may be a signal line for applying a low-level voltage. The power line 132 or the auxiliary line 126 may be connected to the light shielding layer 120. Namely, the low-level voltage may be applied to the light shielding layer 120.

Each of the source electrode 128, the drain electrode 129, the second connection electrode 131, and the power line 132 may be formed of a conductive material, such as metal. For example, each of the source electrode 128, the drain electrode 129, the second connection electrode 131, and the power line 132 may be formed of at least one of Al, Cu, Mo, Ti, Cr, Ni, W, and their alloys.

A third interlayer insulating layer 116 as a sixth insulating layer is disposed on the source electrode 128, the drain electrode 129, the second connection electrode 131, and the power line 132. The third interlayer insulating layer 116 may be formed of an inorganic insulating material or an organic insulating material. For example, the third interlayer insulating layer 116 may include an inorganic insulating material, e.g., silicon nitride, silicon oxide, or silicon oxynitride, or an organic insulating material, e.g., photo-acryl or benzocyclobutene.

The third interlayer insulating layer 116 may be removed from the soft part A2 to substantially correspond to the rigid part A1. As a result, the third interlayer insulating layer 116 may be provided on the first base portion 110a and not provided on the second base portion 110b.

A first auxiliary pad 133, a second auxiliary pad 135, and a repair line 190 are disposed on the third interlayer insulating layer 116.

Each of the first auxiliary pad 133, the second auxiliary pad 135, and the repair line 190 may be formed of a conductive material, such as metal. For example, each of the first auxiliary pad 133, the second auxiliary pad 135, and the repair line 190 may be formed of at least one of Al, Cu, Mo, Ti, Cr, Ni, W, and their alloys. Each of the first auxiliary pad 133, the second auxiliary pad 135, and the repair line 190 may have a single-layered structure or a multi-layered structure.

The first auxiliary pad 133 contacts the pad electrode 127 through a contact hole in the second and third interlayer insulating layers 115 and 116. The second auxiliary pad 135 contacts the semiconductor pattern 121 through a contact hole in the first, second, and third interlayer insulating layers 114, 115 and 116.

The repair line 190 is spaced apart from the first auxiliary pad 133 and is positioned between an end of the rigid part A1 and the first auxiliary pad 133.

The repair line 190 is disposed at a periphery of each rigid part and surrounds the pixel portion of each rigid part A1. For example, a repair line 190 surrounding one pixel P is spaced apart from a repair line 190 surrounding another pixel P adjacent to the one pixel P.

For example, the repair line 190 may have a square or rectangular ring shape. In another example embodiment of the present disclosure, the repair line 190 may be disposed along three sides of the pixel P and may be opened at one side of the pixel P. For example, the repair line 190 may have a “C” or “U” shape.

A passivation layer 117 is disposed on the first auxiliary pad 133, the second auxiliary pad 135, and the repair line 190. The passivation layer 117 may have a single-layered structure or a multi-layered structure of an inorganic insulating material. For example, the passivation layer 117 may include an inorganic insulating material, e.g., silicon nitride, silicon oxide, or silicon oxynitride.

The passivation layer 117 may be removed from the soft part A2 to substantially correspond to the rigid part A1. As a result, the passivation layer 117 may be provided on the first base portion 110a and not provided on the second base portion 110b.

A planarization layer 118 is disposed on the passivation layer 117. The step difference caused by the layers under the planarization layer 118 can be removed by the planarization layer 118 so that the planarization layer 118 may provide a flat top surface. The planarization layer 118 may be formed of an organic insulating material, e.g., photo-acryl or benzocyclobutene.

In another example embodiment of the present disclosure, the passivation layer 117 may be omitted so that the planarization layer 118 may be disposed on the first auxiliary pad 133, the second auxiliary pad 135, and the repair line 190.

The planarization layer 118 may be provided in the rigid part A1 and not in the soft part A2. Namely, the planarization layer 118 may be provided on the first base portion 110a and not provided on the second base portion 110b.

The vertical stretchable line VSL is disposed on the planarization layer 118. An end of the vertical stretchable line VSL is disposed on the planarization layer 118 in the rigid part A1 so that the vertical stretchable line VSL overlaps the repair line 190 and is connected to the first auxiliary pad 133. A center of the vertical stretchable line VSL is disposed on the base substrate 110 in the soft part A2. For example, the vertical stretchable line VSL may contact the first auxiliary pad 133 through a contact hole in the planarization layer 118 and the passivation layer 117.

For example, the repair line 190 may be disposed along an entire side of the rigid part A1, while the vertical stretchable line VSL may be disposed at only a portion of that side of the rigid part A1. Accordingly, in one side of the rigid part A1, a width (or a length) of the repair line 190 may be larger than that of the vertical stretchable line VSL.

The vertical stretchable line VSL extends to be disposed in the soft part A2 and contacts an upper surface of the second base portion 110b of the base substrate 110 in the soft part A2. The vertical stretchable line VSL may contact a side surface of each of the first and second buffer layers 111 and 112, the gate insulating layer 113, the first to third interlayer insulating layers 114, 115 and 116, the passivation layer 117, and the planarization layer 118.

A first electrode 142 and a second electrode 144 are disposed on the planarization layer 118. The first electrode 142 is connected to the drain electrode 129. The first electrode 142 may contact the drain electrode 129 through a contact hole in the planarization layer 118, the passivation layer 117, and the third interlayer insulating layer 116. The second electrode 144 is connected to the second connection electrode 131. The second electrode 144 may contact the second connection electrode 131 through a contact hole in the planarization layer 118, the passivation layer 117, and the third interlayer insulating layer 116.

A third auxiliary pad 146 is disposed on the planarization layer 118. The third auxiliary pad 146 is connected to the second auxiliary pad 135. The third auxiliary pad 146 may contact the second auxiliary pad 135 through a contact hole in the planarization layer 118 and the passivation layer 117.

Similar to a vertical stretchable line VSL, a horizontal stretchable line HSL may be disposed on the planarization layer 118 (in the Y-direction as shown, e.g., in FIG. 1). An end of the horizontal stretchable line HSL may be disposed on the planarization layer 118 in the rigid part A1 so that the horizontal stretchable line HSL overlaps the repair line 190. A center of the horizontal stretchable line HSL may be disposed on the base substrate 110 in the soft part A2.

Each of the vertical stretchable line VSL, the horizontal stretchable line HSL, the first electrode 142, the second electrode 144, and the third auxiliary pad 146 may be formed of a conductive material, such as metal. For example, each of the vertical stretchable line VSL, the horizontal stretchable line HSL, the first electrode 142, the second electrode 144, and the third auxiliary pad 146 may be formed of at least one of Al, Cu, Mo, Ti, Cr, Ni, W, and their alloys.

The light emitting diode 150 as a light emitting element is disposed over the first and second electrodes 142 and 144 and in the rigid part A1. For example, the light emitting diode 150 may be electrically connected to the first and second electrodes 142 and 144 through an adhesive layer 147 including a plurality of conductive balls 149. For example, the adhesive layer 147 may be an anisotropic conductive film (ACF).

The light emitting diode 150 may include a third electrode 152 and a fourth electrode 154 on its lower surface. The third electrode 152 may be a p-type electrode, and the fourth electrode 154 may be an n-type electrode. For example, the third electrode 152 may be an anode, and the fourth electrode 154 may be a cathode.

The light-emitting diode 150 can be provided in the form of a light emitting diode chip including an n-type electrode, an n-type layer, an active layer, a p-type layer, and a p-type electrode.

The third electrode 152 of the light emitting diode 150 overlaps the first electrode 142, and the fourth electrode 154 of the light emitting diode 150 overlaps the second electrode 144. The third electrode 152 is electrically connected to the first electrode 142 through the conductive balls 149 in the adhesive layer 147, and the fourth electrode 154 is electrically connected to the second electrode 144 through the conductive balls 149 in the adhesive layer 147.

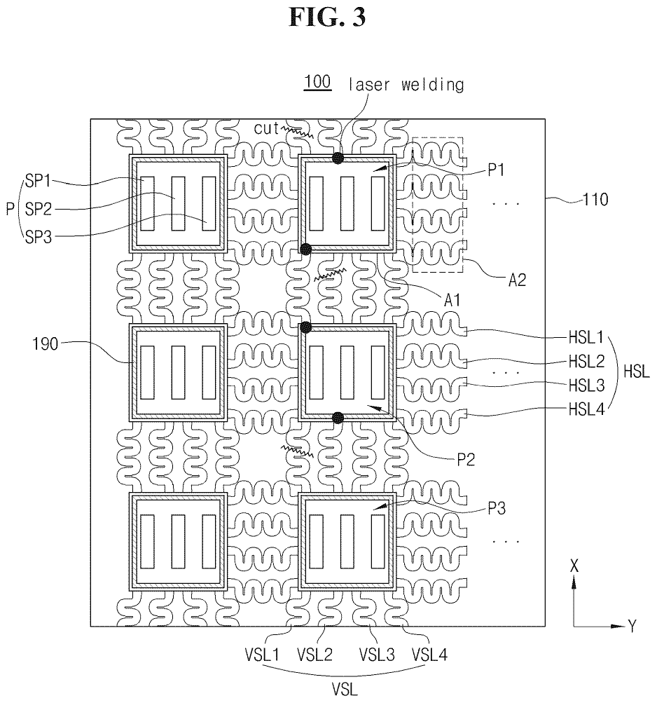

FIG. 3 is a schematic plan view for explaining a repair process in a display panel for a stretchable display device according to the first example embodiment of the present disclosure.

As shown in FIG. 3, a repairing process of a display panel, where a defect occurs, for example, in the first subpixel SP1 of the second pixel P2 so that a line defect in the first direction (or the X-direction) occurs, is explained.

When a defect occurs in the first subpixel SP1 of the second pixel P2, (a) a segment of the first vertical stretchable line VSL1 (e.g., a reference voltage line) applying the reference voltage to the first pixel P1, a segment of the second vertical stretchable line VSL2 (e.g., a data line) between the first subpixel SP1 of the first pixel P1 and the first subpixel SP1 of the second pixel P2, and a segment of the first vertical stretchable VSL1 (e.g., a reference voltage line) between the first subpixel SP1 of the second pixel P2 and the first subpixel SP1 of the third pixel P3 may be cut, and (b) a laser welding process may be performed to i) connect a segment of the second vertical stretchable line VSL2, which applies the data signal to the first subpixel SP1 of the first pixel P1, with the repair line 190 in the first pixel P1, ii) connect a segment of the first vertical stretchable line VSL1 disposed between the first and second pixels P1 and P2 with each of the repair line 190 in the first pixel P1 and the repair line 190 in the second pixel P2, and iii) connect a segment of the second vertical stretchable line VSL2 between the second pixel P2 and the third pixel P3 with the repair line 190 in the second pixel P2.

The (a) and (b) processes may be simultaneously performed. Alternatively, the (b) process may be performed after the (a) process, or the (a) process may be performed after the (b) process.

When the above repair process is performed, the data signal can be applied to the third pixel P3 through the repair line 190 of the first pixel P1, the first vertical stretchable line VSL1 between the first and second pixels P1 and P2, the repair line 190 of the second pixel P2, and the second vertical stretchable line VSL2 between the second and third pixels P2 and P3, bypassing the second pixel P2.

Since the reference voltage can be applied from one side and the other side of the display panel 100, e.g., in the first direction or X-direction, the reference voltage can be applied to the third pixel P3 from the bottom through the first vertical stretchable line VSL1 so that the third pixel P3 can be driven.

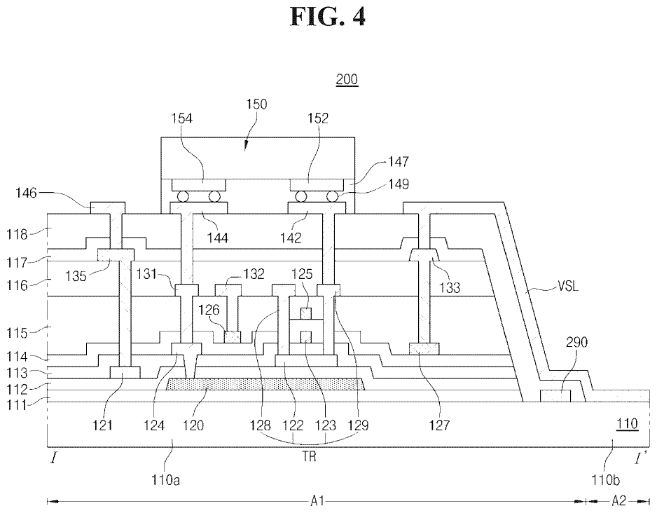

FIG. 4 is a schematic cross-section view of a display panel for a stretchable display device according to a second example embodiment of the present disclosure. FIG. 4 shows a cross-sectional view taken along the line I-I′ in FIG. 1.

The display panel 200 for the stretchable display device according to the second example embodiment of the present disclosure has a difference in a repair line 290 in comparison to the display panel 100 for the stretchable display device according to the first example embodiment of the present disclosure. Accordingly, the below explanation is focused on the repair line 290.

As shown in FIG. 4 in combination with FIG. 1, the repair line 290 is disposed at an edge of the rigid part A1. The first buffer layer 111, the second buffer layer 112, the gate insulating layer 113, the first interlayer insulating layer 114, the second interlayer insulating layer 115, the third interlayer insulating layer 116, and the passivation layer 117 may be removed in the edge of the rigid part A1 so that an upper surface of the base substrate 110 is exposed. The repair line 290 is disposed in the edge of the rigid part A1 and on the exposed upper surface of the base substrate 110.

For example, in a plan view, the repair line 290 is spaced apart from the first auxiliary pad 133 and is positioned between the end of the rigid part A1 and the first auxiliary pad 133. In other words, the repair line 290 is spaced apart from the pad electrode 127 and is positioned between the end of the rigid part A1 and the pad electrode 127.

The repair line 290 surrounds the pixel portion of each rigid part A1. A repair line 290 surrounding one pixel P is spaced apart from a repair line 290 surrounding another pixel P adjacent to the one pixel P.

For example, the repair line 290 may have a square or rectangular ring shape. In another example embodiment of the present disclosure, the repair line 290 may be disposed along three sides of the pixel P and may be opened at one side of the pixel P. For example, the repair line 290 may have a “C” or “U” shape. Namely, the repair line 290 may be disposed along at least three sides of the pixel P.

The repair line 290 may be formed by the same process and formed of the same material as one of the light shielding layer 120, the electrodes 123, 124, 125, 127, 128, 129, and 131, and the pads 133 and 135.

Alternatively, the repair line 290 may be formed on the base substrate 110 before the first buffer layer 111 is formed.

The planarization layer 118 covers the repair line 290. For example, the planarization layer 118 covers a side surface of the first and second buffer layers 111 and 112, the gate insulating layer 113, the first to third interlayer insulating layers 114 to 116, and the passivation layer 117 and extends to cover the repair line 290.

In an edge of the rigid part A1, a lower surface of the planarization layer 118 contacts the repair line 290, and an upper surface of the planarization layer 118 contacts the vertical stretchable line VSL. In addition, in the edge of the rigid part A1, a lower surface of the repair line 290 contacts the base substrate 110, and an upper surface of the repair line 290 contacts the planarization layer 118.

The vertical stretchable line VSL extends along a side surface of the planarization layer 118 into the soft part A2. Accordingly, in an edge of the rigid part A1, the vertical stretchable line VSL overlaps the repair line 290 with the planarization layer 118 therebetween.

For example, the repair line 290 may be disposed along an entire side of the rigid part A1, while the vertical stretchable line VSL may be disposed at only a portion of that side of the rigid part A1. Accordingly, in one side of the rigid part A1, a width (or a length) of the repair line 290 may be larger than that of the vertical stretchable line VSL.

When a line defect occurs in the display panel 200 for the stretchable display device according to the second example embodiment of the present disclosure, one of the stretchable lines VSL and HSL can be cut, and the repair line 290 can be used as a bypass. Accordingly, the line defect in the display panel 200 can be converted into a point defect.

As a result, the display panel 200 and the stretchable display device including the same can provide high quality images.

In addition, by reducing the load on the display panel 200 by converting a defective pixel into a point defect, the lifespan of the display panel 200 can be improved, and the low power consumption can be realized.

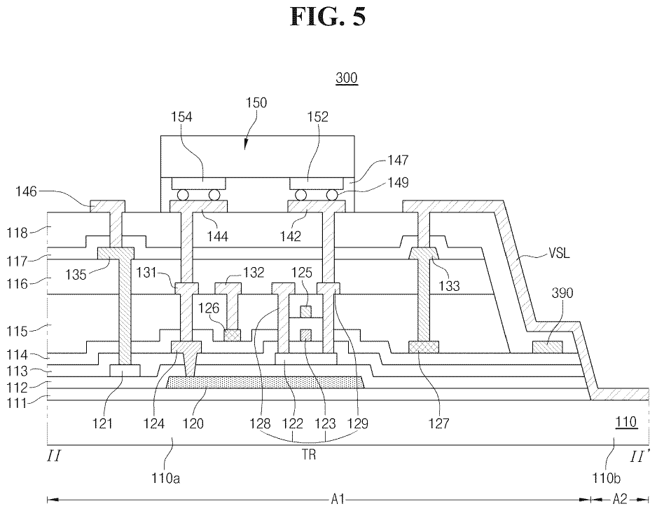

FIG. 5 is a schematic cross-sectional view of a display panel for a stretchable display device according to a third example embodiment of the present disclosure. FIG. 5 shows a cross-section view taken along the line I-I′ in FIG. 1.

The display panel 300 for the stretchable display device according to the third example embodiment of the present disclosure has a difference in a repair line 390 in comparison to the display panel 100 for the stretchable display device according to the first example embodiment of the present disclosure. Accordingly, the below explanation is focused on the repair line 390.

As illustrated in FIG. 5 in combination with FIG. 1, the repair line 390 is disposed on the first interlayer insulating layer 114 and at an edge of the rigid part A1.

In an example embodiment of the present disclosure, the repair line 390 may be disposed at the same layer and formed of the same material as the auxiliary electrode 125, the auxiliary line 126, and the pad electrode 127. For example, the planarization layer 118 over the base substrate 110, an insulating layer, e.g., the first interlayer insulating layer 114, between the base substrate 110 and the planarization layer 118, and a metal layer, e.g., the auxiliary electrode 125, the auxiliary line 126, and the pad electrode 127, between the insulating layer and the planarization layer 118 may be provided, and the repair line 390 may be positioned between the insulating layer and the planarization layer 118.

For example, in a plan view, the repair line 390 is spaced apart from the pad electrode 127 and is positioned between an end of the rigid part A1 and the pad electrode 127.

The repair line 390 surrounds the pixel portion of each rigid part A1. A repair line 390 surrounding one pixel P is spaced apart from a repair line 390 surrounding another pixel P adjacent to the one pixel P.

For example, the repair line 390 may have a square or rectangular ring shape. In another example embodiment of the present disclosure, the repair line 390 may be disposed along three sides of the pixel P and may be opened at one side of the pixel P. For example, the repair line 390 may have a “C” or “U” shape.

The second interlayer insulating layer 115, the third interlayer insulating layer 116, and the passivation layer 117 may be removed in an edge of the rigid part A1 to expose the repair line 390.

Namely, in the display panel 300 of the third example embodiment of the present disclosure, the passivation layer 117, the third interlayer insulating layer 116, and the second interlayer insulating layer 115 are removed in the edge of the rigid part A1 to expose an upper surface of the first interlayer insulating layer 114. The repair line 390 is disposed in the edge of the rigid part A1 and on the exposed upper surface of the first interlayer insulating layer 114.

In other words, each of the first and second buffer layers 111 and 112, the gate insulating layer 113, and the first interlayer insulating layer 114 has a first width, e.g., a first area, and each of the second and third interlayer insulating layers 115 and 116 and the passivation layer 117 has a second width, e.g., a second area, being smaller than the first width. As a result, the upper surface of the first interlayer insulating layer 114 is exposed in the edge of the rigid part A1, and the repair line 390 is disposed in the edge of the rigid part A1 and on the exposed upper surface of the first interlayer insulating layer 114.

The planarization layer 118 covers the repair line 390. For example, the planarization layer 118 covers a side surface of the passivation layer 117, the third interlayer insulating layer 116, and the second interlayer insulating layer 115 and extends to cover the repair line 390. In addition, although not shown in FIG. 5, the planarization layer 118 may further extend to cover a side surface of the first interlayer insulating layer 114, the gate insulating layer 113, the second buffer layer 112, and the first buffer layer 111.

The vertical stretchable line VSL extends along a side surface of the planarization layer 118 into the soft part A2. Accordingly, in an edge of the rigid part A1, the vertical stretchable line VSL overlaps the repair line 390 with the planarization layer 118 therebetween.

For example, the repair line 390 may be disposed along an entire side of the rigid part A1, while the vertical stretchable line VSL may be disposed at only a portion of that side of the rigid part A1. Accordingly, in one side of the rigid part A1, a width (or a length) of the repair line 390 may be larger than that of the vertical stretchable line VSL.

When a line defect occurs in the display panel 300 for the stretchable display device according to the third example embodiment of the present disclosure, one of the stretchable lines VSL and HSL can be cut, and the repair line 390 can be used as a bypass. Accordingly, the line defect in the display panel 300 can be converted into a point defect.

In addition, in an edge of the rigid part A1, where the repair line 390 is disposed, the passivation layer 117, the third interlayer insulating layer 116, and the second interlayer insulating layer 115 are removed, and the planarization layer 118 is disposed between the repair line 390 and the vertical stretchable line VSL. Accordingly, the process of electrically connecting the repair line 390 and the vertical stretchable line VSL can proceed smoothly by laser irradiation.

As a result, the display panel 300 and the stretchable display device including the same can provide high quality images.

In addition, by reducing the load on the display panel 300 by converting a defective pixel into the point defect, the lifespan of the display panel 300 can be improved, and the low power consumption can be realized.

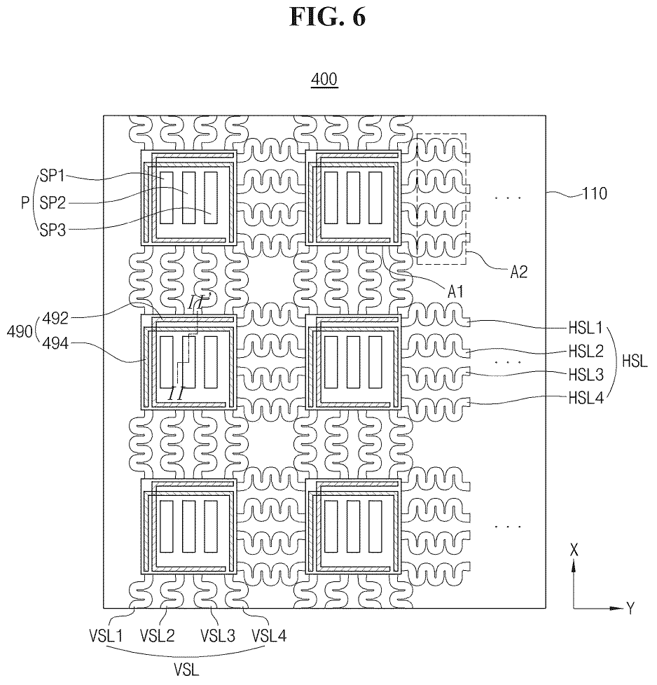

FIG. 6 is a schematic plan view of a display panel for a stretchable display device according to a fourth example embodiment of the present disclosure.

The display panel 400 for the stretchable display device according to the fourth example embodiment of the present disclosure has a difference in a repair line 490 in comparison to the display panel 100 for the stretchable display device according to the first example embodiment of the present disclosure. Accordingly, the below explanation is focused on the repair line 490.

As shown in FIG. 6 in combination with FIG. 1, the display panel 400 includes a repair line 490 surrounding each pixel P. Namely, the repair line 490 is disposed to surround the pixel portion of each rigid part A1. A repair line 490 surrounding a first pixel P is spaced apart from a repair line 490 surrounding a second pixel P adjacent to the first pixel P.

The repair line 490 includes first and second repair lines 492 and 494 each disposed along three sides of the pixel P. Namely, each of the first and second repair lines 492 and 494 is disposed to surround three sides of the pixel portion of the rigid part A1.

In two sides of the rigid part A1, the first and second repair lines 492 and 494 are provided. In one of the two remaining sides of the rigid part A1, one of the first and second repair lines 492 and 494 is provided. In the other of the two remaining sides of the rigid part A1, the other one of the first and second repair lines 492 and 494 is provided.

The rigid part A1 includes a first side in the first direction X, a second side opposite to the first side, a third side in the second direction Y, and a fourth side opposite to the third side. The third side connects the first and second sides. The first repair line 492 is disposed along the first, second, and third sides of the rigid part A1 and is opened at the fourth side of the rigid part A1. The second repair line 494 is disposed along the first, third, and fourth sides of the rigid part A1 and is opened at the second side of the rigid part A1. Each of the first and second repair lines 492 and 494 may have a “C” or “U” shape.

In the first side, the second repair line 494 is provided between the first repair line 492 and the subpixels, and in the second side, the first repair line 492 is provided adjacent to the subpixels without the second repair line 494. As a result, in the first side, the first repair line 492 may be spaced apart from the subpixels by a first distance, and in the second side, the first repair line 492 may be spaced apart from the subpixels by a second distance smaller than the first distance.

In the third side, the first repair line 492 is provided between the second repair line 494 and the first subpixel SP1, and in the fourth side, the second repair line 494 is provided adjacent to the third subpixel SP3 without the first repair line 492. As a result, in the third side, the second repair line 494 may be spaced apart from the first subpixel SP1 by a third distance, and in the fourth side, the second repair line 494 may be spaced apart from the third subpixel SP3 by a fourth distance smaller than the third distance.

In each of the first and third sides of the rigid part A1, the first and second repair lines 492 and 494 are spaced apart from each other. Alternatively, in each of the first and third sides of the rigid part A1, the first and second repair lines 492 and 494 may overlap each other.

In another example embodiment of the present disclosure, each of the first and second repair lines 492 and 494 may have a square or rectangular ring shape.

When a line defect occurs in the display panel 400 for the stretchable display device according to the fourth example embodiment of the present disclosure, one of the stretchable lines VSL and HSL can be cut, and the repair lines 492 and 494 can be used as a bypass. Accordingly, the line defect in the display panel 400 can be converted into a point defect.

When a line defect along the first direction X occurs, the first repair line 492 can be used as a bypass. When a line defect along the second direction Y occurs, the second repair line 494 can be used as a bypass.

The first and second repair lines 492 and 494 in the first side of the rigid part A1 may be spaced apart from each other, and the first repair line 492 may be provided without the second repair line 494 in the second side of the rigid part A1. Accordingly, in the process of connecting the first repair line 492 and the vertical stretchable line VSL by a laser irradiation, an electrical short between the first repair line 492 and the second repair line 494 and/or between the vertical stretchable line VSL and the second repair line 494 can be minimized, suppressed, or prevented.

In addition, the first and second repair lines 492 and 494 in the third side of the rigid part A1 may be spaced apart from each other, and the second repair line 494 may be provided without the first repair line 492 in the fourth side of the rigid part A1. Accordingly, in the process of connecting the second repair line 494 and the horizontal stretchable line HSL by a laser irradiation, an electrical short between the first repair line 492 and the second repair line 494 and/or between the horizontal stretchable line HSL and the first repair line 492 can be minimized, suppressed, or prevented.

As a result, the display panel 400 and the stretchable display device including the same can provide high quality images.

In addition, by reducing the load on the display panel 400 by converting a defective pixel into a point defect, the lifespan of the display panel 400 can be improved, and the low power consumption can be realized.

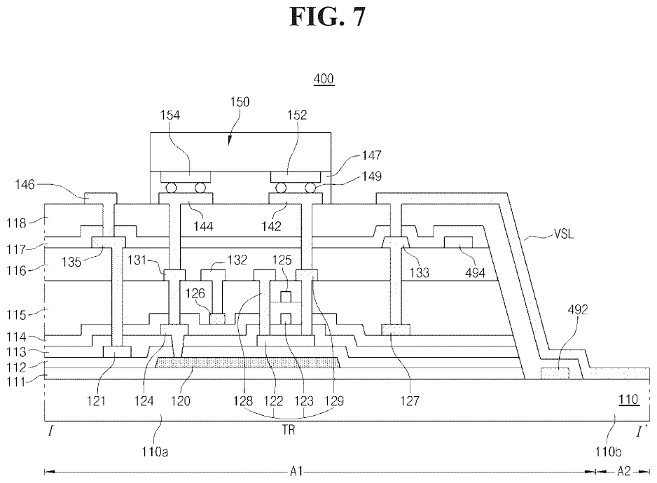

FIG. 7 is a schematic cross-section view of a display panel for a stretchable display device according to the fourth example embodiment of the present disclosure. FIG. 7 shows a cross-sectional view taken along the line II-II′ in FIG. 6.

The display panel 400 for the stretchable display device according to the fourth example embodiment of the present disclosure has a difference in a repair line 490 in comparison to the display panel 100 for the stretchable display device according to the first example embodiment of the present disclosure. Accordingly, the below explanation is focused on the repair line 490.

As illustrated in FIG. 7 in combination with FIG. 6, the second repair line 494 is disposed on the third interlayer insulating layer 116.

The second repair line 494 may be formed of a conductive material, such as metal. For example, the second repair line 494 may be formed of at least one of Al, Cu, Mo, Ti, Cr, Ni, W, and their alloys. The second repair line 494 may be disposed at the same layer and formed of the same material as the first and second auxiliary pads 133 and 135. Each of the first and second auxiliary pads 133 and 135 and the second repair line 494 may have a single-layered structure or a multi-layered structure.

The second repair line 494 is spaced apart from the first auxiliary pad 133 and is positioned between the first auxiliary pad 133 and an end of the rigid part A1. The second repair line 494 may be disposed along three sides of the rigid part A1. For example, the second repair line 494 may be disposed along the first, third and fourth sides and may be opened at the second side of the rigid part A1.

The first repair line 492 is disposed at an edge of the rigid part A1. In the edge of the rigid part A1, the first and second buffer layers 111 and 112, the gate insulating layer 113, the first to third interlayer insulating layers 114 to 116, and the passivation layer 117 may be removed so that an upper surface of the base substrate 110 is exposed. The first repair line 492 may be disposed in the edge of the rigid part A1 and on the exposed upper surface of the base substrate 110.

The first repair line 492 may be formed of a conductive material, such as metal. For example, the first repair line 492 may be formed of at least one of Al, Cu, Mo, Ti, Cr, Ni, W, and their alloys. The first repair line 492 may have a single-layered structure or a multi-layered structure.

For example, in a plan view, the first repair line 492 may be spaced apart from the second repair line 494 and may be positioned between the second repair line 494 and an end of the rigid part A1. In addition, in a plan view, the first repair line 492 may be spaced apart from the pad electrode 127 and be positioned between the pad electrode 127 and an end of the rigid part A1.

The first repair line 492 may be disposed along three sides of the rigid part A1. For example, the first repair line 492 may be disposed along the first, second and third sides of the rigid part A1 and may be opened at the fourth side of the rigid part A1.

The first repair line 492 may be formed by the same process and formed of the same material as any metal layer, e.g., the light shielding layer 120, the electrodes 123, 124, 125, 127, 128, 129, 131, or the lines 126 and 132, between the base substrate 110 and the third interlayer insulating layer 116.

Alternatively, the first repair line 492 may be disposed on the base substrate 110 before forming the first buffer layer 111.

In another example embodiment of the present disclosure, the passivation layer 117, the third interlayer insulating layer 116, and the second interlayer insulating layer 115 may be removed in an edge of the rigid part A1 to expose an upper surface of the first interlayer insulating layer 114. One of the first and second repair lines 492 and 494 may be disposed in the edge of the rigid part A1 and on the exposed upper surface of the first interlayer insulating layer 114.

In FIG. 7, the first repair line 492 is positioned on the base substrate 110, and the second repair line 494 is positioned on the third interlayer insulating layer 116.

In yet another example embodiment of the present disclosure, one of the first and second repair lines 492 and 494 may be positioned on the base substrate 110, and the other one of the first and second repair lines 492 and 494 may be positioned on any insulating layer, e.g., the first interlayer insulating layer 114, between the base substrate 110 and the planarization layer 118.

In still another example embodiment of the present disclosure, one of the first and second repair lines 492 and 494 may be positioned on the third interlayer insulating layer 116, and the other one of the first and second repair lines 492 and 494 may be positioned on another insulating layer, e.g., the first interlayer insulating layer 114, between the base substrate 110 and the planarization layer 118.

In yet another example embodiment of the present disclosure, one of the first and second repair lines 492 and 494 may be positioned between the planarization layer 118 and an insulating layer positioned between the base substrate 110 and the planarization layer 118, and the other one of the first and second repair line 492 and 494 may be disposed between the base substrate 110 and the insulating layer.

The planarization layer 118 covers the first and second repair lines 492 and 494. For example, the planarization layer 118 may be positioned over the second repair line 494 with the passivation layer 117 therebetween and may be positioned directly on the first repair line 492.

For example, in an edge of the rigid part A1, the planarization layer 118 covers the second repair line 494 and extends to over the first repair line 492 and a side surface of each of the first and second buffer layers 111 and 112, the gate insulating layer 113, the first to third interlayer insulating layers 114 to 116, and the passivation layer 117.

The vertical stretchable line VSL is disposed on the planarization layer 118. An end of the vertical stretchable line VSL is disposed on the planarization layer 118 in the rigid part A1 so that the vertical stretchable line VSL overlaps the second repair line 494 and is connected to the first auxiliary pad 133.

The vertical stretchable line VSL extends along a side surface of the planarization layer 118 into the soft part A2. Accordingly, in an edge of the rigid part A1, the vertical stretchable line VSL overlaps the first repair line 492 with the planarization layer 118 therebetween.

Namely, only the planarization layer 118 is provided between the first repair line 492 and the vertical stretchable line VSL, while the planarization layer 118 and the passivation layer 117 are provided between the second repair line 494 and the vertical stretchable line VSL. Alternatively, where the passivation layer 117 is omitted, only the planarization layer 118 may be provided between the first repair line 492 and the vertical stretchable line VSL and between the second repair line 494 and the vertical stretchable line VSL.

For example, each of the first and second repair lines 492 and 494 may be disposed along an entire side of the rigid part A1, while the vertical stretchable line VSL may be disposed at only a portion of that side of the rigid part A1. Accordingly, in one side of the rigid part A1, a width (or a length) of each of the first and second repair lines 492 and 494 may be larger than that of the vertical stretchable line VSL.

When a line defect occurs in the display panel 400 for the stretchable display device according to the fourth example embodiment of the present disclosure, one of the stretchable lines VSL and HSL can be cut, and the first and/or second repair lines 492 and 494 can be used as a bypass. Accordingly, the line defect in the display panel 400 can be converted into a point defect.

As a result, the display panel 400 and the stretchable display device including the same can provide high quality images.

In addition, by reducing the load on the display panel 400 by converting a defective pixel into a point defect, the lifespan of the display panel 400 can be improved, and the low power consumption can be realized.

In addition, line defects in the first and second directions X and Y can be repaired using the first and second repair lines 492 and 494.

It will be apparent to those skilled in the art that various modifications and variations can be made in the embodiments of the present disclosure without departing from the spirit or scope of the present disclosure. Thus, it is intended that the modifications and variations cover this disclosure provided they come within the scope of the appended claims and their equivalents.

What is claimed is:

1. A display panel for a stretchable display device, the display panel having a rigid part and a soft part and comprising:
a base substrate in the rigid part and the soft part;
a planarization layer over the base substrate and in the rigid part;
a pixel on the base substrate in the rigid part and including:
a first electrode over the planarization layer;
a second electrode over the planarization layer and spaced apart from the first electrode; and
a light emitting element electrically connected to the first and second electrodes;
a first stretchable line disposed along a first direction in a plan view, the first stretchable line having an end on the planarization layer in the rigid part and a center portion on the base substrate in the soft part; and
a repair line between the base substrate and the planarization layer,
wherein the repair line is disposed along at least three sides of the pixel in the plan view and overlaps the first stretchable line.

2. The display panel of claim 1, wherein:
the first stretchable line includes a first line segment connected to one side of the pixel and a second line segment connected to an opposite side of the pixel; and
the repair line overlaps the first and second line segments.

3. The display panel of claim 1, wherein the repair line has a ring shape surrounding the pixel in the plan view.

4. The display panel of claim 1, wherein:
a lower surface of the repair line contacts the base substrate, and an upper surface of the repair line contacts the planarization layer; and
an upper surface of the planarization layer contacts the first stretchable line.

5. The display panel of claim 1, further comprising:
a metal layer between the base substrate and the planarization layer in the rigid part,
wherein the repair line is disposed on a same underlying layer and is formed of a same material as the metal layer.

6. The display panel of claim 5, further comprising:
a first insulating layer between the base substrate and the metal layer in the rigid part,
wherein the repair line is on the first insulating layer.

7. The display panel of claim 6, further comprising:
a second insulating layer between the planarization layer and the metal layer in the rigid part,
wherein the second insulating layer has a smaller width than the first insulating layer to expose a portion of an upper surface of the first insulating layer,
wherein the repair line is disposed on the exposed portion of the upper surface of the first insulating layer, and
wherein the planarization layer contacts the repair line.

8. The display panel of claim 1, wherein the repair line is disposed along three sides of the pixel and has an opening at one side of the pixel in the plan view.

9. The display panel of claim 1, further comprising:
a plurality of rigid parts, including the rigid part; and
a plurality of soft parts, including the soft part, connected respectively between the plurality of rigid parts,
wherein the base substate is in the plurality of rigid parts, and the plurality of rigid parts respectively include a plurality of pixels on the base substrate, including the pixel, and
wherein the first stretchable line is electrically connected to a line of pixels arranged along the first direction, among the plurality of pixels.

10. The display panel of claim 1, further comprising:
a second stretchable line disposed along a second direction different from the first direction in the plan view,
wherein the second stretchable line has an end on the planarization layer in the rigid part and a center portion on the base substrate in the soft part.

11. The display panel of claim 10, wherein the repair line overlaps the second stretchable line.

12. The display panel of claim 10, wherein:
the rigid part includes a first side, a second side opposite to the first side in the first direction, a third side connecting the first and second sides, and a fourth side opposite to the third side in the second direction; and
the repair line includes:
a first repair line overlapping the first stretchable line in the first and second sides; and
a second repair line overlapping the second stretchable line in the third and fourth sides.

13. The display panel of claim 12, wherein, in the plan view:
the first repair line is disposed along the first, second, and third sides of the rigid part and not along the fourth side of the rigid part; and
the second repair line is disposed along the first, third, and fourth sides of the rigid part and not along the second side of the rigid part.

14. The display panel of claim 13, wherein:
the pixel includes a plurality of subpixels;
at the first side, the first repair line is spaced apart from a subpixel nearest the first side, among the subpixels, by a first distance; and
at the second side, the first repair line is spaced apart from a subpixel nearest the second side, among the subpixels, by a second distance smaller than the first distance.

15. The display panel of claim 13, wherein:
the pixel includes a plurality of subpixels;
at the third side, the second repair line is spaced apart from a subpixel nearest the third side, among the subpixels, by a third distance; and
at the fourth side, the second repair line is spaced apart from a subpixel nearest the fourth side, among the subpixels, by a fourth distance smaller than the third distance.

16. The display panel of claim 12, wherein the first repair line and the second repair line are disposed at different layers.

17. The display panel of claim 16, further comprising:
a first insulating layer between the base substrate and the planarization layer,
wherein one of the first and second repair lines is disposed between the first insulating layer and the planarization layer.

18. The display panel of claim 12, further comprising:
a first insulating layer between the base substrate and the planarization layer; and
a second insulating layer between the planarization layer and the first insulating layer,
wherein one of the first and second repair lines is disposed between the second insulating layer and the planarization layer.

19. The display panel of claim 18, wherein:
the second insulating layer has a smaller width than the first insulating layer to expose a portion of an upper surface of the first insulating layer;
the other of the first and second repair lines is disposed on the exposed portion of the upper surface of the first insulating layer; and
the planarization layer contacts the other of the first and second repair lines.

20. The display panel of claim 10, further comprising:
a plurality of rigid parts, including the rigid part, arranged in the first direction and the second direction; and
a plurality of soft parts, including the soft part, connected respectively between the plurality of rigid parts,
wherein the base substate is in the plurality of rigid parts, and the plurality of rigid parts respectively include a plurality of pixels on the base substrate, including the pixel,
wherein the first stretchable line is electrically connected to a line of pixels arranged along the first direction, among the plurality of pixels, and
wherein the second stretchable line is electrically connected to a line of pixels arranged along the second direction, among the plurality of pixels.
